(19) United States
(12) Patent Application Publication
(10) Pub. No.: US 2025/0022495 A1
(43) Pub. Date: Jan. 16, 2025

(54) Circuits And Methods For Generating Adjustable Signal Pulses That Control Writes To Memory Cells

(71) Applicant: Altera Corporation, San Jose, CA (US)

(72) Inventor: Wee Leam Teoh, Bayan Lepas (MY)

(73) Assignee: Altera Corporation, San Jose, CA (US)

(21) Appl. No.: 18/904,611

(22) Filed: Oct. 2, 2024

(51) Int. Cl. G11C 7/10; G11C 7/22; G11C 8/08

(52) U.S. Cl. CPC G11C 7/1096; G11C 7/222; G11C 8/08

(57) ABSTRACT

An integrated circuit includes a memory bit cell having a transistor coupled to a data line and a write pulse generation circuit coupled to the memory bit cell. The write pulse generation circuit generates a pulse in a word line signal that controls the transistor. The write pulse generation circuit adjusts a width of the pulse in the word line signal based on a write time of a write operation to the memory bit cell performed through the data line and the transistor.

### BACKGROUND

Configurable integrated circuits (ICs) can be configured by users to implement desired custom logic functions. In a typical scenario, a logic designer uses computer-aided design (CAD) tools to design a custom circuit design. When the design process is complete, the computer-aided design tools generate an image containing configuration data bits. The configuration data bits are then loaded into configuration memory elements that configure configurable logic circuits in the integrated circuit to perform the functions of the custom circuit design.

### BRIEF DESCRIPTION OF DRAWINGS

FIG. 1 is a schematic diagram of a write pulse generation circuit for a bit cell for use in an adaptive data write scheme.

FIG. 2 is a timing diagram that illustrates examples of waveforms of various signals and states in the write pulse generation circuit and the bit cell of FIG. 1.

FIG. 3 is a diagram that illustrates an example of an array of bit cells that are controlled by the write pulse generation circuit of FIG. 1.

FIG. 4 is a diagram of an illustrative example of a configurable integrated circuit (IC).

FIG. 5 illustrates a block diagram of a system that can be used to implement a circuit design to be programmed into a programmable logic device using design software.

FIG. 6 is a diagram that depicts an example of a programmable logic device that includes fabric dies and base dies that are connected to one another via microbumps.

FIG. 7 is a block diagram illustrating a computing system configured to implement one or more aspects of the embodiments described herein.

### DETAILED DESCRIPTION

In a conventional LUTRAM (Look-up Table Random Access Memory) in a field programmable gate array (FPGA) data write scheme, there is no inherent interrelationship between the LUTRAM write time and the write pulse width. As a result, the dynamic write margin is not effectively optimized across all PVT (process, voltage, temperature) conditions. This lack of optimization hampers the overall performance of the data write scheme.

According to some examples discloses herein, data write techniques for memories (e.g., LUTRAMs) are provided for generating write pulses that can dynamically adjust the write pulse width based on the write time during write operations. These techniques offer a significant advancement in the field of data write operations (e.g., for FPGA LUTRAMs). Unlike conventional approaches, these techniques utilize the importance of adapting the pulse width of write signals to match the specific requirements of the write time for memories, such as LUTRAMs.

These data write techniques offer an important advantage with low write pulse transitions immediately after the completion of a write operation. The low write pulse transition signifies that the write pulse width is automatically adjusted based on the write time. As a result, these techniques enable the optimization of write performance. These data write techniques can provide enhanced write data performance, resource utilization, and power efficiency.

One or more specific examples are described below. In an effort to provide a concise description of these examples, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

Throughout the specification, and in the claims, the terms “connected” and “connection” mean a direct electrical connection between the circuits that are connected, without any intermediary devices. The terms “coupled” and “coupling” mean either a direct electrical connection between circuits or an indirect electrical connection through one or more passive or active intermediary devices that allows the transfer of information between circuits. The term “circuit” may mean one or more passive and/or active electrical components that are arranged to cooperate with one another to provide a desired function.

This disclosure discusses integrated circuit devices, including configurable (programmable) integrated circuits, such as field programmable gate arrays (FPGAs) and programmable logic devices. As discussed herein, an integrated circuit (IC) can include hard logic and/or soft logic. The circuits in an integrated circuit device (e.g., in a configurable IC) that are configurable by an end user are referred to as “soft logic.” “Hard logic” generally refers to circuits in an integrated circuit device that have substantially less configurable features than soft logic or no configurable features.

In a conventional LUTRAM data write scheme, a write pulse generation circuit is used to produce a fixed write pulse. The fixed write pulse is generated from a system clock and is used to activate an access transistor during the write operation. The main disadvantage of a conventional LUTRAM data write scheme is that there is no interrelationship between the LUTRAM write time and write pulse width. The lack of an interrelationship between the write time and the write pulse width means that the dynamic write margin, which represents the tolerance for variations in PVT (process, voltage, temperature), is not effectively optimized.

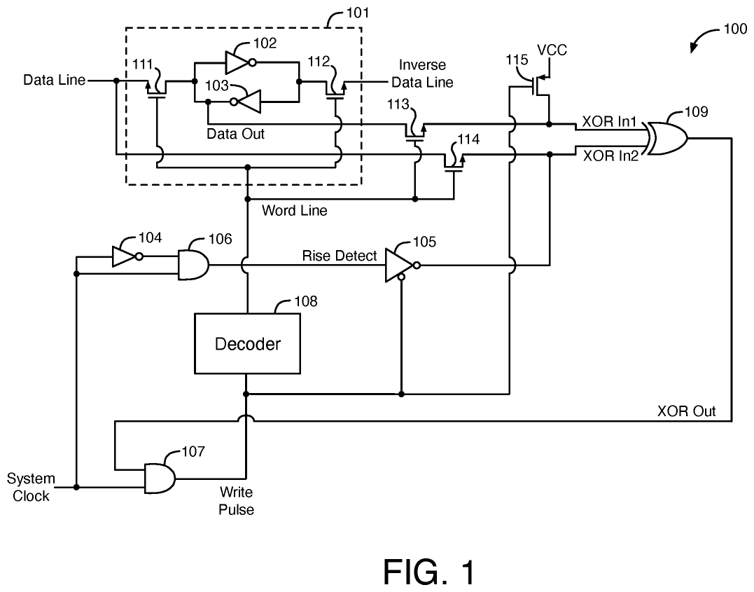

Figure (FIG. 1 is a schematic diagram of a write pulse generation circuit 100 for a LUTRAM bit cell 101 for use in an adaptive LUTRAM data write scheme. The LUTRAM (Look-up Table Random Access Memory) bit cell 101 includes two cross-coupled inverter circuits 102-103 and two n-channel field-effect transistors (FETs) 111-112 that function as access transistors. The LUTRAM bit cell 101 is also referred to herein as a memory bit cell, a memory cell, or a memory circuit. LUTRAM bit cell 101 can be coupled to a look-up table (LUT) (not shown). The write pulse generation circuit 100 includes inverter circuit 104, AND logic gate circuits 106-107, tri-state inverter circuit 105, decoder circuit 108, XOR logic gate circuit 109, n-channel field-effect transistors (FETs) 113 and 114, and p-channel field-effect transistor (FET) 115.

Write pulse generation circuit 100 and LUTRAM 101 can be formed in any type of integrated circuit (IC), such as a configurable IC (e.g., a field programmable gate array (FPGA) or programmable logic device), a microprocessor IC, a graphics processing unit IC, a memory IC, an application specific IC, a transceiver IC, etc. In the examples described below, write pulse generation circuit 100 is in a configurable IC, such as an FPGA or programmable logic device (PLD).

A Data Line is coupled to the source of transistor 111, and an Inverse Data Line is coupled to the source of transistor 112. The source of transistor 115 is coupled to receive a supply voltage VCC. A System Clock signal (i.e., a periodic signal) is provided to inputs of the AND logic gate 107, the inverter circuit 104, and the AND logic gate 106.

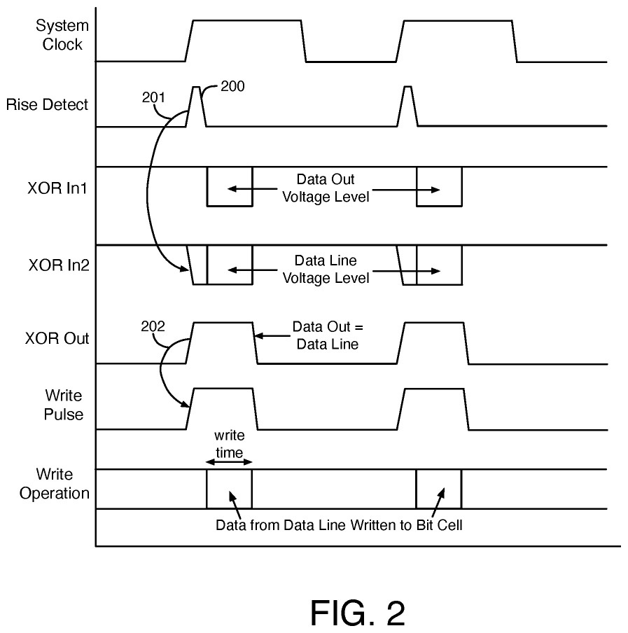

FIG. 2 is a timing diagram that illustrates examples of waveforms of various signals and states in the write pulse generation circuit 100 and in the LUTRAM bit cell 101 of FIG. 1. The operation of the write pulse generation circuit 100 and the LUTRAM bit cell 101 of FIG. 1 is described below in detail with respect to the timing diagram of FIG. 2.

The output signal of the AND logic gate circuit 106 is referred to as the Rise Detect signal in FIGS. 1-2. The output signal of the AND logic gate circuit 107 is referred to as the Write Pulse signal in FIGS. 1-2. The decoder circuit 108 generates a Word Line signal on a Word Line in response to the Write Pulse signal. The Word Line signal is provided through the Word Line to the gates of transistors 111-114. The input signals to the XOR logic gate circuit 109 are referred to as XOR In1 and XOR In2 in FIGS. 1-2. The output signal of the XOR logic gate circuit 109 is referred to as the XOR Out signal in FIGS. 1-2.

Before a rising edge of the System Clock signal, the Write Pulse signal is in a logic low state (i.e., a logic 0) as shown in FIG. 2, and as a result, the decoder circuit 108 causes the Word Line signal to be in a logic low state in response to the Write Pulse signal. The access transistors 111-112 and the pass gate transistors 113-114 are off in response to the logic low state of the Word Line signal. Additionally, the Write Pulse signal being in a logic low state turns the pull-up p-channel FET 115 on, which pulls the XOR In1 signal up to supply voltage VCC (representing a logic 1). Also, the Write Pulse signal being in a logic low state turns on the tri-state inverter circuit 105.

When the System Clock signal is in a logic low state, the output signal Rise Detect of AND logic gate circuit 106 is also in a logic low state. As a result, the tri-state inverter circuit 105 drives the XOR In2 signal to a logic high state (i.e., a logic 1), because the Rise Detect signal is in a logic low state (a logic 0) and the tri-state inverter circuit 105 is on. Because both of the input signals XOR In1 and XOR In2 are in logic high states, the XOR logic gate circuit 109 drives its output signal XOR Out to a logic low state, as shown on the left side of FIG. 2, when the System Clock signal is in a logic low state.

The inverter circuit 104 is an inverting delay circuit that can generate a short delay. In response to a rising edge in the System Clock signal, the AND logic gate circuit 106 generates a short duration pulse 200 in the Rise Detect signal (in response to the short delay of inverter circuit 104) that causes the tri-state inverter circuit 105 to generate a falling edge transition in the XOR In2 signal from a logic high state to a logic low state, as shown by arrow 201 in FIG. 2. As a result, the XOR logic gate circuit 109 generates a rising edge transition in the XOR Out signal from a logic low state to a logic high state, as shown in FIG. 2, because the inputs to XOR logic gate circuit 109 are in different logic states (i.e., XOR In1 is a logic 1 and XOR In2 is logic 0). In response to the rising edge transition in the XOR Out signal, the AND logic gate circuit 107 generates a rising edge transition in the Write Pulse signal from a logic low state to a logic high state, as shown by arrow 202 in FIG. 2. In response to the rising edge transition in the Write Pulse signal, the pull-up FET 115 turns off, and the tri-state inverter circuit 105 turns off.

Also, in response to the rising edge transition in the Write Pulse signal, the decoder circuit 108 generates a rising edge transition in the Word Line signal from a logic low state to a logic high state, turning on each of the access transistors 111-112 and each of the pass gate transistors 113-114. The pass gate FETs 113-114 function transparently, propagating the signal Data Out in bit cell 101 and the signal on the Data Line to the inputs of XOR logic gate circuit 109. As a result, the XOR In1 signal receives the voltage level of the Data Out signal, and the XOR In2 signal receives the voltage level of the signal on the Data Line, as shown in FIG. 2.

During a write operation to the LUTRAM bit cell 101, FETs 111-112 are on, and a data bit from the Data Line and an inverted data bit from the Inverse Data Line are written into the LUTRAM bit cell 101 as the Data Out signal through the access FETs 111-112, respectively, as shown in the depiction of the Write Operation at the bottom of FIG. 2. After the write operation is completed, the logic state of the signal on the Data Line is equal to the logic state of the Data Out signal.

Also, after the write operation is completed, the XOR logic gate circuit 109 causes the XOR Out signal to transition back to a logic low state (i.e., generate a falling edge in XOR Out), as shown in FIG. 2, because the XOR logic gate circuit 109 input signals XOR In1 and XOR In2 are in the same logic states. The input signals XOR In1 and XOR In2 are in the same logic states, because FETs 113-114 are on, and the signal on the Data Line and the Data Out signal are in the same logic states after the write operation.

In response to the falling edge in the XOR Out signal, the AND logic gate circuit 107 generate a falling edge in the Write Pulse signal from a logic high state to a logic low state, as shown in FIG. 2. In response to the falling edge in the Write Pulse signal, the decoder circuit 108 generates a falling edge in the Word Line signal from a logic high state to a logic low state, which turns off the access FETs 111-112 and turns off the pass gate FETs 113-114. The write pulse cycle and the write operation are then complete. Thus, the write pulse generation circuit 100 automatically adjusts the widths of the logic high pulses in the Write Pulse signal and in the Word Line signal based on the write time (and based on the completion) of the write operation, as shown in FIG. 2. As a result, the LUTRAM write performance is optimized.

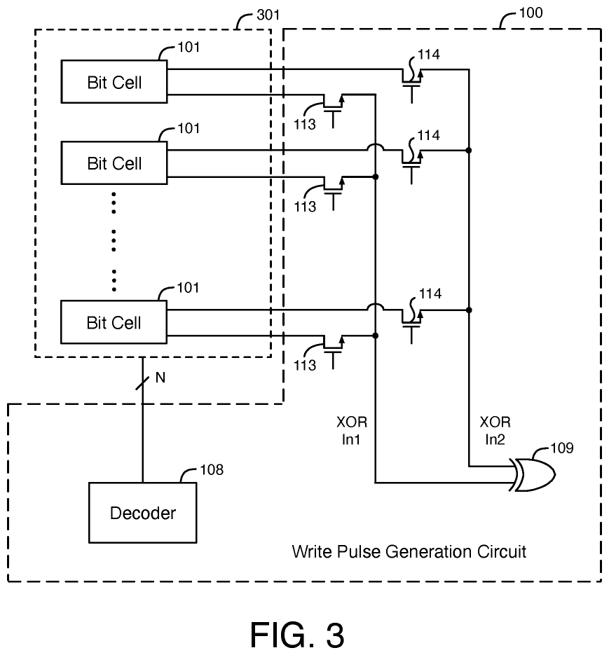

FIG. 3 is a diagram that illustrates an example of an array 301 of LUTRAM bit cells 101 that are controlled by the write pulse generation circuit 100 of FIG. 1. The LUTRAM bit cells 101 and the write pulse generation circuit 100 of FIG. 3 can be formed in a single integrated circuit die. In the example of FIG. 3, the array 301 includes 3 or more LUTRAM bit cells 101 that are each coupled to a pair of pass gate transistors (i.e., FETs) 113-114 in the write pulse generation circuit 100. The pass gate FETs 113-114 are coupled to the inputs of the XOR logic gate circuit 109 as shown in FIG. 3. The FETs 113 generate input signal XOR In1, and the FETs 114 generate input signal XOR In2. The decoder circuit 108 generates N-bit Word Line signals on the Word Lines that are transmitted to the array 301. Each of the Word Line signals is provided to one of the bit cells 101 in the array 301. As an example that is not intended to be limiting, the decoder circuit 108 can generate 32-bits of Word Line signals that are provided to 32 bit cells 101 in array 301. The remaining circuitry in the write pulse generation circuit 100 is not shown in FIG. 3. The write pulse generation circuit 100 of FIG. 3 operates as disclosed herein with respect to FIGS. 1-2.

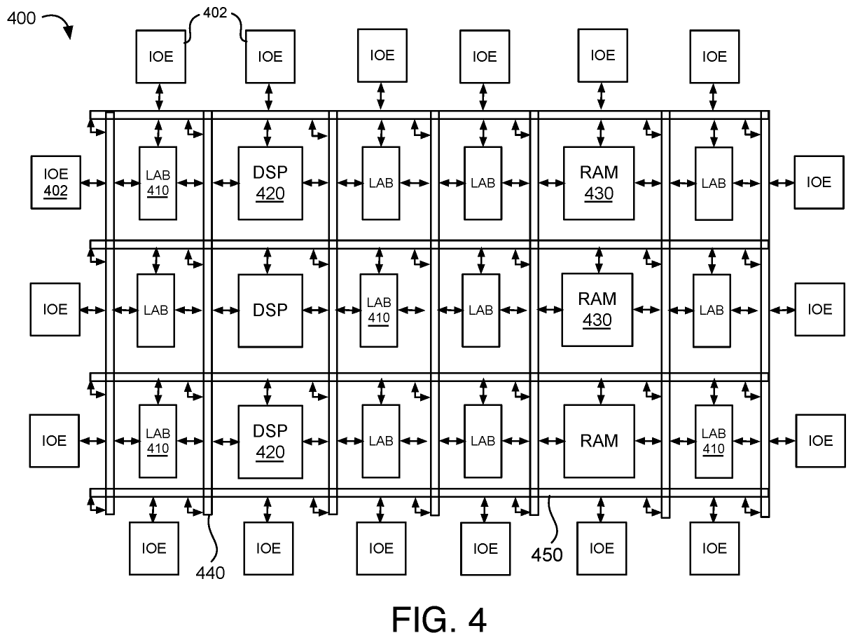

FIG. 4 is a diagram of an illustrative example of a configurable integrated circuit (IC) 400. Configurable IC 400 is an example of an IC that can include the write pulse generation circuit 100 and the bit cells 101 disclosed herein with respect to FIGS. 1-3. As shown in FIG. 4, the configurable integrated circuit 400 includes a two-dimensional array of configurable logic circuit blocks, including logic array blocks (LABs) 410 and other configurable logic circuit blocks, such as random access memory (RAM) blocks 430 and digital signal processing (DSP) blocks 420, for example. Configurable logic circuit blocks, such as LABs 410, can include smaller configurable regions (e.g., configurable logic elements, configurable logic blocks, or adaptive logic modules (ALMs)) that receive input signals and perform custom functions on the input signals to produce output signals.

The configurable integrated circuit 400 also includes programmable interconnect circuitry in the form of vertical routing channels 440 (i.e., interconnects formed along a vertical axis of configurable integrated circuit 400) and horizontal routing channels 450 (i.e., interconnects formed along a horizontal axis of configurable integrated circuit 400), each routing channel including at least one track to route at least one wire. One or more of the routing channels 440 and/or 450 can be part of a network-on-chip (NOC) having router circuits.

In addition, the configurable integrated circuit 400 has input/output elements (IOEs) 402 (e.g., including IO circuit blocks) for driving signals off of configurable integrated circuit 400 and for receiving signals from other devices. Input/output elements 402 can include parallel input/output circuitry, serial data transceiver circuitry, differential receiver and transmitter circuitry, or other circuitry used to connect one integrated circuit to another integrated circuit. Input/output elements 402 can include general purpose input/output (GPIO) circuitry (e.g., on the top and bottoms edges of IC 400), high-speed input/output (HSIO) circuitry (e.g., on the left edge of IC 400), and on-package input/output (OPIOs) circuitry (e.g., on the right edge of IC 400).

As shown, input/output elements 402 can be located around the periphery of the IC. If desired, the configurable integrated circuit 400 can have input/output elements 402 arranged in different ways. For example, input/output elements 402 can form one or more columns of input/output elements that can be located anywhere on the configurable integrated circuit 400 (e.g., distributed evenly across the width of the configurable integrated circuit). If desired, input/output elements 402 can form one or more rows of input/output elements (e.g., distributed across the height of the configurable integrated circuit). Alternatively, input/output elements 402 can form islands of input/output elements that can be distributed over the surface of the configurable integrated circuit 400 or clustered in selected areas.

Note that other routing topologies, besides the topology of the interconnect circuitry depicted in FIG. 4, can be used. For example, the routing topology can include wires that travel diagonally or that travel horizontally and vertically along different parts of their extent as well as wires that are perpendicular to the device plane in the case of three dimensional integrated circuits, and the driver of a wire can be located at a different point than one end of a wire. The routing topology can include global wires that span substantially all of configurable integrated circuit 400, fractional global wires such as wires that span part of configurable integrated circuit 400, staggered wires of a particular length, smaller local wires, or any other suitable interconnection resource arrangement.

Furthermore, it should be understood that examples disclosed herein may be implemented in any type of integrated circuit. If desired, the functional blocks of such an integrated circuit can be arranged in more levels or layers in which multiple functional blocks are interconnected to form still larger blocks. Other device arrangements can use functional blocks that are not arranged in rows and columns.

Configurable integrated circuit 400 can also contain programmable memory elements. The memory elements can be loaded with configuration data (also called programming data) using input/output elements (IOEs) 402. Once loaded, the memory elements each provide a corresponding static control signal that controls the operation of an associated functional block (e.g., LABs 410, DSP 420, RAM 430, or input/output elements 402).

In a typical scenario, the outputs of the loaded memory elements are applied to the gates of field-effect transistors in a functional block to turn certain transistors on or off and thereby configure the logic in the functional block including the routing paths. Programmable logic circuit elements that are controlled in this way include parts of multiplexers (e.g., multiplexers used for forming routing paths in interconnect circuits), look-up tables, logic arrays, AND, OR, NAND, and NOR logic gates, pass gates, etc.

The memory elements can use any suitable volatile and/or non-volatile memory structures such as random-access-memory (RAM) cells, fuses, antifuses, programmable read-only-memory memory cells, mask-programmed and laser-programmed structures, combinations of these structures, etc. Because the memory elements are loaded with configuration data during programming, the memory elements are sometimes referred to as configuration memory or programmable memory elements.

The programmable memory elements can be organized in a configuration memory array consisting of rows and columns. A data register that spans across all columns and an address register that spans across all rows can receive configuration data. The configuration data can be shifted onto the data register. When the appropriate address register is asserted, the data register writes the configuration data to the configuration memory elements of the row that was designated by the address register.

Configurable integrated circuit 400 can include configuration memory that is organized in sectors, whereby a sector can include the configuration bits that specify the function and/or interconnections of the subcomponents and wires in or crossing that sector. Each sector can include separate data and address registers.

The configurable IC 400 of FIG. 4 is merely one example of an IC that can be used with embodiments disclosed herein. The embodiments disclosed herein can be used with any suitable electronic integrated circuit or system. For example, the embodiments disclosed herein can be used with numerous types of electronic devices such as processor integrated circuits, central processing units, memory integrated circuits, graphics processing unit integrated circuits, application specific standard products (ASSPs), application specific integrated circuits (ASICs), and configurable logic integrated circuits. Examples of configurable logic integrated circuits include programmable arrays logic (PALs), programmable logic arrays (PLAs), field programmable logic arrays (FPLAs), electrically programmable logic devices (EPLDs), electrically erasable programmable logic devices (EEPLDs), logic cell arrays (LCAs), complex programmable logic devices (CPLDs), and field programmable gate arrays (FPGAs), just to name a few.

The integrated circuits disclosed in one or more embodiments herein can be part of a data processing system that includes one or more of the following components: a processor; memory; input/output circuitry; and peripheral devices. The data processing system can be used in a wide variety of applications, such as computer networking, data networking, instrumentation, video processing, digital signal processing, or any suitable other application. The integrated circuits can be used to perform a variety of different logic functions.

In general, software and data for performing any of the functions disclosed herein can be stored in non-transitory computer readable storage media. Non-transitory computer readable storage media is tangible computer readable storage media that stores data and software for access at a later time, as opposed to media that only transmits propagating electrical signals (e.g., wires). The software code may sometimes be referred to as software, data, program instructions, instructions, or code. The non-transitory computer readable storage media can, for example, include computer memory chips, non-volatile memory such as non-volatile random-access memory (NVRAM), one or more hard drives (e.g., magnetic drives or solid state drives), one or more removable flash drives or other removable media, compact discs (CDs), digital versatile discs (DVDs), Blu-ray discs (BDs), other optical media, and floppy diskettes, tapes, or any other suitable memory or storage device(s).

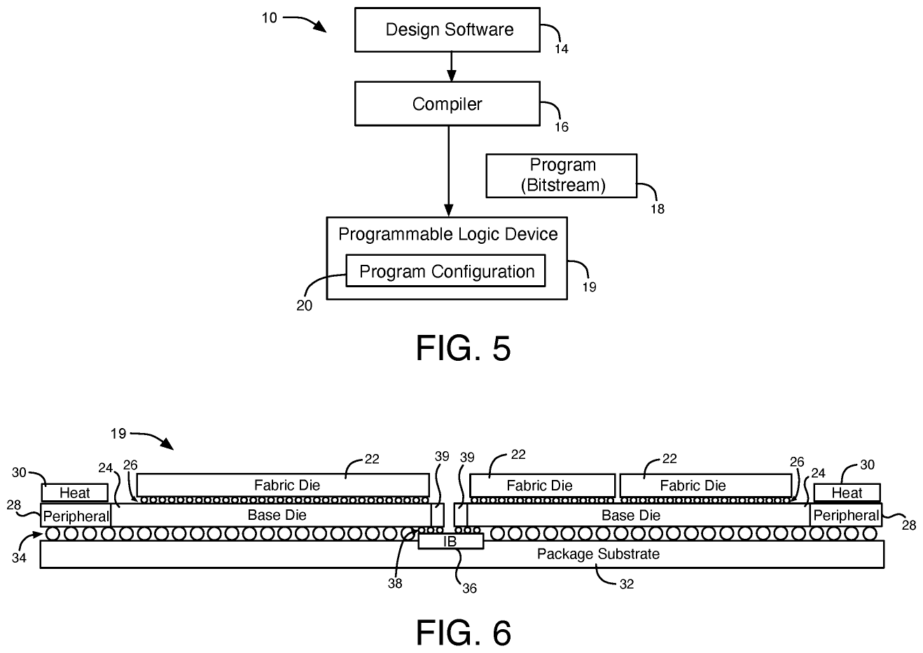

FIG. 5 illustrates a block diagram of a system 10 that can be used to implement a circuit design to be programmed onto a programmable logic device 19 using design software. A designer can implement circuit design functionality on an integrated circuit, such as a reconfigurable programmable logic device 19 (e.g., a field programmable gate array (FPGA)). The designer can implement the circuit design to be programmed onto the programmable logic device 19 using design software 14. The design software 14 can use a compiler 16 to generate a low-level circuit-design program (bitstream) 18, sometimes known as a program object file and/or configuration program, that programs the programmable logic device 19. Thus, the compiler 16 can provide machine-readable instructions representative of the circuit design to the programmable logic device 19. For example, the programmable logic device 19 can receive one or more programs (bitstreams) 18 that describe the hardware implementations that should be stored in the programmable logic device 19. A program (bitstream) 18 can be programmed into the programmable logic device 19 as a configuration program 20. The configuration program 20 can, in some cases, represent an accelerator function to perform for machine learning, video processing, voice recognition, image recognition, or other highly specialized task.

In some implementations, a programmable logic device can be any integrated circuit device that includes a programmable logic device with two separate integrated circuit die where at least some of the programmable logic fabric is separated from at least some of the fabric support circuitry that operates the programmable logic fabric. One example of such a programmable logic device is shown in FIG. 6, but many others can be used, and it should be understood that this disclosure is intended to encompass any suitable programmable logic device where programmable logic fabric and fabric support circuitry are at least partially separated on different integrated circuit die.

FIG. 6 is a diagram that depicts an example of the programmable logic device 19 that includes three fabric die 22 and two base die 24 that are connected to one another via microbumps 26. In the example of FIG. 6, at least some of the programmable logic fabric of the programmable logic device 19 is in the three fabric die 22, and at least some of the fabric support circuitry that operates the programmable logic fabric is in the two base die 24. For example, some of the circuitry of configurable IC 400 shown in FIG. 4 (e.g., LABs 410, DSP 420, and RAM 430) can be located in the fabric die 22 and some of the circuitry of IC 400 (e.g., input/output elements 402) can be located in the base die 24.

Although the fabric die 22 and base die 24 appear in a one-to-one relationship or a two-to-one relationship in FIG. 6, other relationships can be used. For example, a single base die 24 can attach to several fabric die 22, or several base die 24 can attach to a single fabric die 22, or several base die 24 can attach to several fabric die 22 (e.g., in an interleaved pattern). Peripheral circuitry 28 can be attached to, embedded within, and/or disposed on top of the base die 24, and heat spreaders 30 can be used to reduce an accumulation of heat on the programmable logic device 19. The heat spreaders 30 can appear above, as pictured, and/or below the package (e.g., as a double-sided heat sink). The base die 24 can attach to a package substrate 32 via conductive bumps 34. In the example of FIG. 6, two pairs of fabric die 22 and base die 24 are shown communicatively connected to one another via an interconnect bridge 36 (e.g., an embedded multi-die interconnect bridge (EMIB)) and microbumps 38 at bridge interfaces 39 in base die 24.

In combination, the fabric die 22 and the base die 24 can operate in combination as a programmable logic device 19 such as a field programmable gate array (FPGA). It should be understood that an FPGA can, for example, represent the type of circuitry, and/or a logical arrangement, of a programmable logic device when both the fabric die 22 and the base die 24 operate in combination. Moreover, an FPGA is discussed herein for the purposes of this example, though it should be understood that any suitable type of programmable logic device can be used.

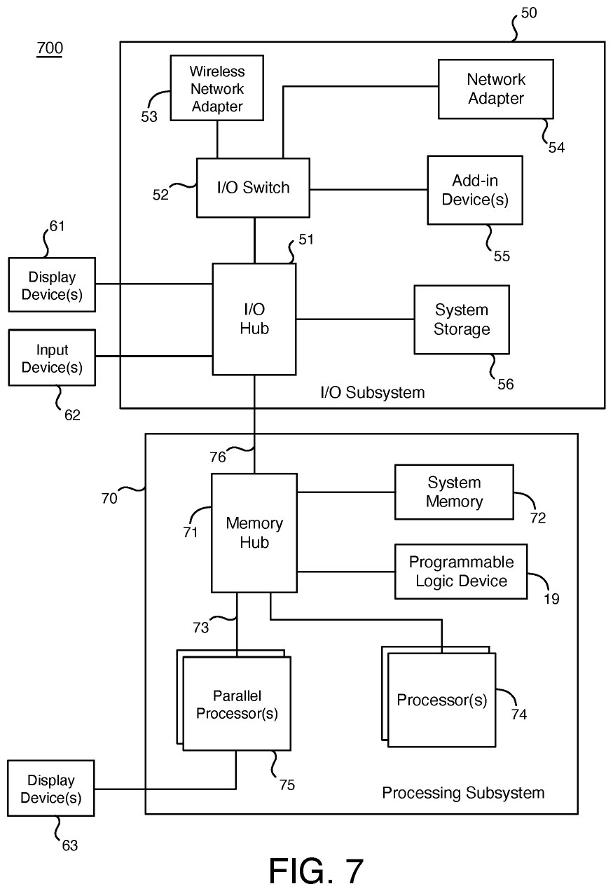

FIG. 7 is a block diagram illustrating a computing system 700 configured to implement one or more aspects of the embodiments described herein. The computing system 700 includes a processing subsystem 70 having one or more processor(s) 74, a system memory 72, and a programmable logic device 19 communicating via an interconnection path that can include a memory hub 71. The memory hub 71 can be a separate component within a chipset component or can be integrated within the one or more processor(s) 74. The memory hub 71 couples with an input/output (I/O) subsystem 50 via a communication link 76. The I/O subsystem 50 includes an input/output (I/O) hub 51 that can enable the computing system 700 to receive input from one or more input device(s) 62. Additionally, the I/O hub 51 can enable a display controller, which can be included in the one or more processor(s) 74, to provide outputs to one or more display device(s) 61. In one embodiment, the one or more display device(s) 61 coupled with the I/O hub 51 can include a local, internal, or embedded display device.

In one embodiment, the processing subsystem 70 includes one or more parallel processor(s) 75 coupled to memory hub 71 via a bus or other communication link 73. The communication link 73 can use one of any number of standards based communication link technologies or protocols, such as, but not limited to, PCI Express, or can be a vendor specific communications interface or communications fabric. In one embodiment, the one or more parallel processor(s) 75 form a computationally focused parallel or vector processing system that can include a large number of processing cores and/or processing clusters, such as a many integrated core (MIC) processor. In one embodiment, the one or more parallel processor(s) 75 form a graphics processing subsystem that can output pixels to one of the one or more display device(s) 61 coupled via the I/O Hub 51. The one or more parallel processor(s) 75 can also include a display controller and display interface (not shown) to enable a direct connection to one or more display device(s) 63.

Within the I/O subsystem 50, a system storage unit 56 can connect to the I/O hub 51 to provide a storage mechanism for the computing system 700. An I/O switch 52 can be used to provide an interface mechanism to enable connections between the I/O hub 51 and other components, such as a network adapter 54 and/or a wireless network adapter 53 that can be integrated into the platform, and various other devices that can be added via one or more add-in device(s) 55. The network adapter 54 can be an Ethernet adapter or another wired network adapter. The wireless network adapter 53 can include one or more of a Wi-Fi, Bluetooth, near field communication (NFC), or other network device that includes one or more wireless radios.

The computing system 700 can include other components not shown in FIG. 7, including other port connections, optical storage drives, video capture devices, and the like, that can also be connected to the I/O hub 51. Communication paths interconnecting the various components in FIG. 7 can be implemented using any suitable protocols, such as PCI (Peripheral Component Interconnect) based protocols (e.g., PCI-Express), or any other bus or point-to-point communication interfaces and/or protocol(s), such as the NV-Link high-speed interconnect, or interconnect protocols known in the art.

In one embodiment, the one or more parallel processor(s) 75 incorporate circuitry optimized for graphics and video processing, including, for example, video output circuitry, and constitutes a graphics processing unit (GPU). In another embodiment, the one or more parallel processor(s) 75 incorporate circuitry optimized for general purpose processing, while preserving the underlying computational architecture. In yet another embodiment, components of the computing system 700 can be integrated with one or more other system elements on a single integrated circuit. For example, the one or more parallel processor(s) 75, memory hub 71, processor(s) 74, and I/O hub 51 can be integrated into a system on chip (SoC) integrated circuit. Alternatively, the components of the computing system 700 can be integrated into a single package to form a system in package (SIP) configuration. In one embodiment, at least a portion of the components of the computing system 700 can be integrated into a multi-chip module (MCM), which can be interconnected with other multi-chip modules into a modular computing system.

The computing system 700 shown herein is illustrative. Other variations and modifications are also possible. The connection topology, including the number and arrangement of bridges, the number of processor(s) 74, and the number of parallel processor(s) 75, can be modified as desired. For instance, in some embodiments, system memory 72 is connected to the processor(s) 74 directly rather than through a bridge, while other devices communicate with system memory 72 via the memory hub 71 and the processor(s) 74. In other alternative topologies, the parallel processor(s) 75 are connected to the I/O hub 51 or directly to one of the one or more processor(s) 74, rather than to the memory hub 71. In other embodiments, the I/O hub 51 and memory hub 71 can be integrated into a single chip. Some embodiments can include two or more sets of processor(s) 74 attached via multiple sockets, which can couple with two or more instances of the parallel processor(s) 75.

Some of the particular components shown herein are optional and may not be included in all implementations of the computing system 700. For example, any number of add-in cards or peripherals can be supported, or some components can be eliminated. Furthermore, some architectures can use different terminology for components similar to those illustrated in FIG. 7. For example, the memory hub 71 can be referred to as a Northbridge in some architectures, while the I/O hub 51 can be referred to as a Southbridge.
Additional examples are now described. Example 1 is an integrated circuit comprising: a memory bit cell comprising a first transistor coupled to a data line; and a write pulse generation circuit coupled to the memory bit cell, wherein the write pulse generation circuit generates a first pulse in a word line signal that controls the first transistor, and wherein the write pulse generation circuit adjusts a width of the first pulse in the word line signal based on a write time of a write operation to the memory bit cell performed through the data line and the first transistor.
In Example 2, the integrated circuit of Example 1 may optionally include, wherein the memory bit cell further comprises a second transistor coupled to an inverse data line, and wherein the write operation to the memory bit cell is performed through the inverse data line and the second transistor.
In Example 3, the integrated circuit of any one of Examples 1-2 may optionally include, wherein the write pulse generation circuit comprises a second transistor coupled to the data line, a third transistor coupled to cross-coupled inverter circuits in the memory bit cell, and a logic gate circuit comprising a first input coupled to the second transistor and a second input coupled to the third transistor.
In Example 4, the integrated circuit of any one of Examples 1-3 may optionally include, wherein the write pulse generation circuit comprises an XOR logic gate circuit comprising inputs that are coupled to the data line and to the memory bit cell in response to the first pulse in the word line signal.
In Example 5, the integrated circuit of Example 4 may optionally include, wherein the write pulse generation circuit further comprises a decoder circuit that generates the first pulse in the word line signal in response to a second pulse in an output signal of the XOR logic gate circuit.
In Example 6, the integrated circuit of any one of Examples 1-5 may optionally include, wherein the write pulse generation circuit comprises an inverter circuit and an AND gate circuit comprising an input coupled to the inverter circuit, and wherein the inverter circuit and the AND gate circuit generate a second pulse in a rise detect signal in response to a transition in a clock signal.
In Example 7, the integrated circuit of Example 6 may optionally include, wherein the write pulse generation circuit further comprises a decoder circuit and an XOR gate circuit that generates a third pulse in an output signal in response to the second pulse in the rise detect signal, and wherein the decoder circuit generates the first pulse in the word line signal in response to the third pulse in the output signal.
In Example 8, the integrated circuit of any one of Examples 1-7 may optionally include, wherein the write pulse generation circuit comprises an AND gate circuit and a decoder circuit that generates the first pulse in the word line signal in response to a second pulse in an output signal of the AND gate circuit, and wherein the AND gate circuit generates the second pulse in the output signal in response to a logic transition in a clock signal.
In Example 9, the integrated circuit of any one of Examples 1-8 may optionally include, wherein the integrated circuit is a configurable integrated circuit comprising configuration random access memory.
Example 10 is a method for writing a bit to a memory circuit, the method comprising: generating a first logic transition on a word line that turns on a first access transistor to begin a write of the bit to the memory circuit through a data line and the first access transistor using a pulse generation circuit; and generating a second logic transition that is opposite the first logic transition on the word line that turns off the first access transistor in response to a completion of the write of the bit to the memory circuit using the pulse generation circuit.
In Example 11, the method of Example 10 may optionally include, wherein generating the first logic transition on the word line further comprises generating the first logic transition on the word line that turns on a second access transistor to begin the write of an inverted bit to the memory circuit through an inverse data line and the second access transistor.
In Example 12, the method of any one of Examples 10-11 may optionally include, wherein generating the first logic transition on the word line further comprises generating the first logic transition on the word line in response to a third logic transition in a clock signal.
In Example 13, the method of any one of Examples 10-12 further comprises: coupling inputs of an XOR logic gate circuit to the data line and the memory circuit through pass gate transistors in response to the first logic transition.
In Example 14, the method of any one of Examples 10-13 further comprises: decoupling inputs of an XOR logic gate circuit from the data line and the memory circuit through pass gate transistors in response to the second logic transition.
In Example 15, the method of any one of Examples 10-14 may optionally include, wherein generating the second logic transition on the word line further comprises generating the second logic transition on the word line in response to the data line and a node in the memory circuit having a same logic state.
In Example 16, the method of any one of Examples 10-15 may optionally include, wherein generating the first logic transition on the word line further comprises generating the first logic transition on the word line using an inverting delay circuit, a first logic gate circuit couped to a first output of the inverting delay circuit, a tri-state inverter circuit coupled to a second output of the first logic gate circuit, and an XOR logic gate circuit coupled to a third output of the tri-state inverter circuit.
Example 17 is a write pulse generation circuit comprising: a logic gate circuit that causes a first logic transition on a word line to turn on an access transistor that begins a write of a bit to a memory cell through a data line and the first access transistor, wherein the logic gate circuit causes a second logic transition that is opposite the first logic transition on the word line to turn off the access transistor in response to completion of the write of the bit to the memory cell.
In Example 18, the write pulse generation circuit of Example 17 may optionally include, wherein the logic gate circuit causes the second logic transition on the word line in response to the data line and a node in the memory cell having a same logic state.
In Example 19, the write pulse generation circuit of any one of Examples 17-18 further comprises: pass gate transistors that couple inputs of the logic gate circuit to the data line and the memory cell in response to the first logic transition and that decouple the inputs of the logic gate circuit from the data line and the memory cell in response to the second logic transition.
In Example 20, the write pulse generation circuit of any one of Examples 17-19 may optionally include, wherein the logic gate circuit is an XOR logic gate circuit.

The foregoing description of the exemplary embodiments has been presented for the purpose of illustration. The foregoing description is not intended to be exhaustive or to be limiting to the examples disclosed herein. The foregoing is merely illustrative of the principles of this disclosure and various modifications can be made by those skilled in the art. The foregoing embodiments may be implemented individually or in any combination.

What is claimed is:

1. An integrated circuit comprising:
a memory bit cell comprising a first transistor coupled to a data line; and
a write pulse generation circuit coupled to the memory bit cell, wherein the write pulse generation circuit generates a first pulse in a word line signal that controls the first transistor, and wherein the write pulse generation circuit adjusts a width of the first pulse in the word line signal based on a write time of a write operation to the memory bit cell performed through the data line and the first transistor.

2. The integrated circuit of claim 1, wherein the memory bit cell further comprises a second transistor coupled to an inverse data line, and wherein the write operation to the memory bit cell is performed through the inverse data line and the second transistor.

3. The integrated circuit of claim 1, wherein the write pulse generation circuit comprises a second transistor coupled to the data line, a third transistor coupled to cross-coupled inverter circuits in the memory bit cell, and a logic gate circuit comprising a first input coupled to the second transistor and a second input coupled to the third transistor.

4. The integrated circuit of claim 1, wherein the write pulse generation circuit comprises an XOR logic gate circuit comprising inputs that are coupled to the data line and to the memory bit cell in response to the first pulse in the word line signal.

5. The integrated circuit of claim 4, wherein the write pulse generation circuit further comprises a decoder circuit that generates the first pulse in the word line signal in response to a second pulse in an output signal of the XOR logic gate circuit.

6. The integrated circuit of claim 1, wherein the write pulse generation circuit comprises an inverter circuit and an AND gate circuit comprising an input coupled to the inverter circuit, and wherein the inverter circuit and the AND gate circuit generate a second pulse in a rise detect signal in response to a transition in a clock signal.

7. The integrated circuit of claim 6, wherein the write pulse generation circuit further comprises a decoder circuit and an XOR gate circuit that generates a third pulse in an output signal in response to the second pulse in the rise detect signal, and wherein the decoder circuit generates the first pulse in the word line signal in response to the third pulse in the output signal.

8. The integrated circuit of claim 1, wherein the write pulse generation circuit comprises an AND gate circuit and a decoder circuit that generates the first pulse in the word line signal in response to a second pulse in an output signal of the AND gate circuit, and wherein the AND gate circuit generates the second pulse in the output signal in response to a logic transition in a clock signal.

9. The integrated circuit of claim 1, wherein the integrated circuit is a configurable integrated circuit comprising configuration random access memory.

10. A method for writing a bit to a memory circuit, the method comprising:
generating a first logic transition on a word line that turns on a first access transistor to begin a write of the bit to the memory circuit through a data line and the first access transistor using a pulse generation circuit; and
generating a second logic transition that is opposite the first logic transition on the word line that turns off the first access transistor in response to a completion of the write of the bit to the memory circuit using the pulse generation circuit.

11. The method of claim 10, wherein generating the first logic transition on the word line further comprises generating the first logic transition on the word line that turns on a second access transistor to begin the write of an inverted bit to the memory circuit through an inverse data line and the second access transistor.

12. The method of claim 10, wherein generating the first logic transition on the word line further comprises generating the first logic transition on the word line in response to a third logic transition in a clock signal.

13. The method of claim 10 further comprising:
coupling inputs of an XOR logic gate circuit to the data line and the memory circuit through pass gate transistors in response to the first logic transition.

14. The method of claim 10 further comprising:
decoupling inputs of an XOR logic gate circuit from the data line and the memory circuit through pass gate transistors in response to the second logic transition.

15. The method of claim 10, wherein generating the second logic transition on the word line further comprises generating the second logic transition on the word line in response to the data line and a node in the memory circuit having a same logic state.

16. The method of claim 10, wherein generating the first logic transition on the word line further comprises generating the first logic transition on the word line using an inverting delay circuit, a first logic gate circuit couped to a first output of the inverting delay circuit, a tri-state inverter circuit coupled to a second output of the first logic gate circuit, and an XOR logic gate circuit coupled to a third output of the tri-state inverter circuit.

17. A write pulse generation circuit comprising:
a logic gate circuit that causes a first logic transition on a word line to turn on an access transistor that begins a write of a bit to a memory cell through a data line and the first access transistor,
wherein the logic gate circuit causes a second logic transition that is opposite the first logic transition on the word line to turn off the access transistor in response to completion of the write of the bit to the memory cell.

18. The write pulse generation circuit of claim 17, wherein the logic gate circuit causes the second logic transition on the word line in response to the data line and a node in the memory cell having a same logic state.

19. The write pulse generation circuit of claim 17 further comprising:
pass gate transistors that couple inputs of the logic gate circuit to the data line and the memory cell in response to the first logic transition and that decouple the inputs of the logic gate circuit from the data line and the memory cell in response to the second logic transition.

20. The write pulse generation circuit of claim 17, wherein the logic gate circuit is an XOR logic gate circuit.
